(19) United States
(12) Patent Application Publication
(10) Pub. No.: US 2018/0241859 A1
(43) Pub. Date: Aug. 23, 2018

(54) PRINTED CIRCUIT BOARD AND MOBILE TERMINAL MOUNTED THE SAME

(71) Applicant: LG ELECTRONICS INC., Seoul (KR)

(72) Inventors: Youngmin CHO, Seoul (KR); Kipyoung KIM, Seoul (KR); Kipoung KIM, Seoul (KR); Youngjik LEE, Seoul (KR)

(73) Assignee: LG ELECTRONICS INC., Seoul (KR)

(21) Appl. No.: 15/824,132

(22) Filed: Nov. 28, 2017

(30) Foreign Application Priority Data
Feb. 17, 2017 (KR) 10-2017-0021778

(51) Int. Cl. H04M 1/02; G06F 1/16; H04B 1/3827; H05K 1/14; H05K 9/00

(52) U.S. Cl. CPC H04M 1/0277; G06F 1/1626; H04B 1/3833; H04M 1/02; H05K 2201/047; H05K 9/0028; H01L 2924/15311; H01L 2924/19105; H05K 1/14

(57) ABSTRACT

There is disclosed a mobile terminal comprising a printed circuit board, a chipset comprising a die and connected to the printed circuit board through BGA (Ball Grid Array), and a solder pad array provided in a predetermine region of the printed circuit board, corresponding to the BGA, wherein the solder pad array comprises a NSMD array region provided in a region corresponding to the die and having NSMD pads and a SMD array region provided in an outer region of the NSMD array region and having SMD pads, to solve the disadvantages in impact resistance or heat resistance which might be generated in the chipset mounted printed circuit board structure.

### CROSS-REFERENCE TO RELATED APPLICATIONS

This application claims priority to Korean Patent Application No. 10-2017-0021778 filed on Feb. 17, 2017 in Korea, the entire contents of which is hereby incorporated by reference in its entirety.

### BACKGROUND OF THE DISCLOSURE

### Field of the Disclosure

Embodiments of the present disclosure relate to a loading method between a chipset and a printed circuit board which are provided in a mobile terminal and a mobile terminal having the same mounted therein.

### Background of the Disclosure

A chipset which is provided in a mobile terminal functions as a brain for controlling functions of the mobile terminal. Such a chipset is loaded in a printed circuit board provided in a mobile terminal and operatively connected with the other components of the mobile terminal and operate.

In case such a chipset is soldered in a printed circuit board, the reliability of the soldering connection between the chipset and the printed circuit board becomes a major issue. Impact resistance which is a property resistant to a shock or impact and thermostability which is a property of resistance to heat become standards for determining the reliability of the connection between the chipset and the printed circuit board.

Meanwhile, with a trend to miniaturization and weight lightening, the miniaturization of the chipset and the miniaturization and weight lightening of the printed circuit board has been tried and continued.

Another trend for slimming the printed circuit board may be said as a part of the miniaturization and weight lightening of the mobile terminal. However, the slimming printed circuit board could be negative to the impact resistance of the mobile terminal, more specifically, the chipset and the printed circuit board.

Moreover, the high intensity in a chipset process might raise the heat generated per a predetermined area and the standards of heat resistance as well.

As a result, the soldering connection between the chipset and the printed circuit board requires both the heat resistance and the impact resistance and also higher and higher standards.

Ball Grid Array (BGA) has been used a lot as one example of the soldering connection.

Conventional BGA soldering method is classified into SMD soldering and NSMD soldering, based on characteristics of a shape of a pad and a solder mask which are provided on a chipset loaded surface of a printed circuit board. Such SMD soldering has a high impact resistance and a low heat resistance. NSMD soldering has a high heat resistance and a low impact resistance.

Accordingly, it is difficult for the conventional soldering methods to satisfy the two conditions which fit the recent trends simultaneously.

### SUMMARY OF THE DISCLOSURE

Accordingly, an object of the present invention is to address the above-noted and other problems.

An object of the present disclosure is to solve the disadvantages of the impact or heat resistance which might occur in the structure for loading the chipset in the printed circuit board which mentioned above.

Embodiments of the present disclosure may provide a mobile terminal comprising a printed circuit board; a chipset comprising a die and connected to the printed circuit board through BGA (Ball Grid Array); and a solder pad array provided in a predetermine region of the printed circuit board, corresponding to the BGA, wherein the solder pad array comprises a NSMD array region provided in a region corresponding to the die and having NSMD pads; and a SMD array region provided in an outer region of the NSMD array region and having SMD pads.

The SMD array region may be provided inside of an edge of the die and the NSMD array region is provided outside of an edge of the die.

The BGA may comprise a first BGA region connected with the die through a bump; and a second BGA region provided in the other portion except the first BGA region, and the NSMD array region may be corresponding to the first BGA region and the SMD array region is corresponding to the second BGA region.

A border between the NSMD array region and the SMD array region may be corresponding to an edge of the die or outer to the edge of the die.

The outermost line of the solder pad array may form a rectangular edge.

The SMD array region may form a ‘□’ shape, and the NSMD array region may be provided in the SMD array region.

The chipset may be a system-on-chip.

Embodiments of the present disclosure may also provide a mobile terminal comprising a non-conductive substrate; and a solder pad array provided in a predetermined region of the non-conductive substrate, wherein the solder pad array comprises a SMD array region having outer n lines of SMD pads; and a NSMD array region provided in the SMD array region and having NSMD pads.

The outermost line of the solder pad array may form a rectangular shaped edge.

The SMD array region may form a ‘□’ shape, and the NSMD array region may be provided in the SMD array region.

According to at least one embodiment mentioned above, the mobile terminal has following effects.

The mobile terminal according to at least one embodiment mentioned above is capable of satisfying both heat resistance and impact resistance.

Furthermore, the mobile terminal according to at least one embodiment is capable of being applied to all types of chipsets having the die, in other words, it has versatility.

Still further, the mobile terminal according to at least one embodiment has a great effect on the system-on-chip.

Further scope of applicability of the present invention will become apparent from the detailed description given hereinafter. However, it should be understood that the detailed description and specific examples, while indicating preferred embodiments of the invention, are given by illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below and the accompanying drawings, which are given by illustration only, and thus are not limitative of the present invention, and wherein:

FIG. 1a is a block diagram to describe a mobile terminal in accordance with the present disclosure;

FIGS. 1b and 1c are conceptual diagrams of one example of the mobile terminal, viewed from different directions;

FIG. 2 is an exploded perspective diagram of the mobile terminal;

FIG. 3 is a conceptual diagram of a chipset and a printed circuit board before they are soldered to each other;

FIG. 4 is a conceptual diagram of the chipset and the printed circuit board after they are soldered to each other;

FIG. 5 is a diagram illustrating connection between the printed circuit board and a solder ball in BGA soldering;

FIG. 6 is a diagram illustrating connection between the printed circuit board and a solder ball in BGA soldering;

FIG. 7 is a conceptual diagram illustrating one embodiment of soldering between the printed circuit board and the chipset;

FIG. 8 is a conceptual diagram illustrating another embodiment of soldering between the printed circuit board and the chipset;

FIG. 9 is a diagram illustrating one embodiment of a solder pad array in accordance to the present disclosure;

FIG. 10 is a diagram illustrating another embodiment of a soldering surface of the chipset with respect to the printed circuit board;

FIG. 11 is a diagram illustrating one embodiment of the printed circuit board in accordance with the present disclosure;

FIG. 12 is a diagram illustrating another embodiment of the printed circuit board in accordance with the present disclosure; and

FIG. 13 is a diagram illustrating a further embodiment of the printed circuit board in accordance with the present disclosure.

### DESCRIPTION OF SPECIFIC EMBODIMENTS

Description will now be given in detail according to exemplary embodiments disclosed herein, with reference to the accompanying drawings. For the sake of brief description with reference to the drawings, the same or equivalent components may be provided with the same reference numbers, and description thereof will not be repeated. In general, a suffix such as “module” and “unit” may be used to refer to elements or components. Use of such a suffix herein is merely intended to facilitate description of the specification, and the suffix itself is not intended to give any special meaning or function. In the present disclosure, that which is well-known to one of ordinary skill in the relevant art has generally been omitted for the sake of brevity. The accompanying drawings are used to help easily understand various technical features and it should be understood that the embodiments presented herein are not limited by the accompanying drawings. As such, the present disclosure should be construed to extend to any alterations, equivalents and substitutes in addition to those which are particularly set out in the accompanying drawings.

It will be understood that although the terms first, second, etc. may be used herein to describe various elements, these elements should not be limited by these terms. These terms are generally only used to distinguish one element from another.

It will be understood that when an element is referred to as being “connected with” another element, the element can be directly connected with the other element or intervening elements may also be present. In contrast, when an element is referred to as being “directly connected with” another element, there are no intervening elements present.

A singular representation may include a plural representation unless it represents a definitely different meaning from the context. Terms such as “include” or “has” are used herein and should be understood that they are intended to indicate an existence of several components, functions or steps, disclosed in the specification, and it is also understood that greater or fewer components, functions, or steps may likewise be utilized.

Mobile terminals presented herein may be implemented using a variety of different types of terminals. Examples of such terminals include cellular phones, smart phones, user equipment, laptop computers, digital broadcast terminals, personal digital assistants (PDAs), portable multimedia players (PMPs), navigators, portable computers (PCs), slate PCs, tablet PCs, ultra-books, wearable devices (for example, smart watches, smart glasses, head mounted displays (HMDs)), and the like.

By way of non-limiting example only, further description will be made with reference to particular types of mobile terminals. However, such teachings apply equally to other types of terminals, such as those types noted above. In addition, these teachings may also be applied to stationary terminals such as digital TV, desktop computers, and the like.

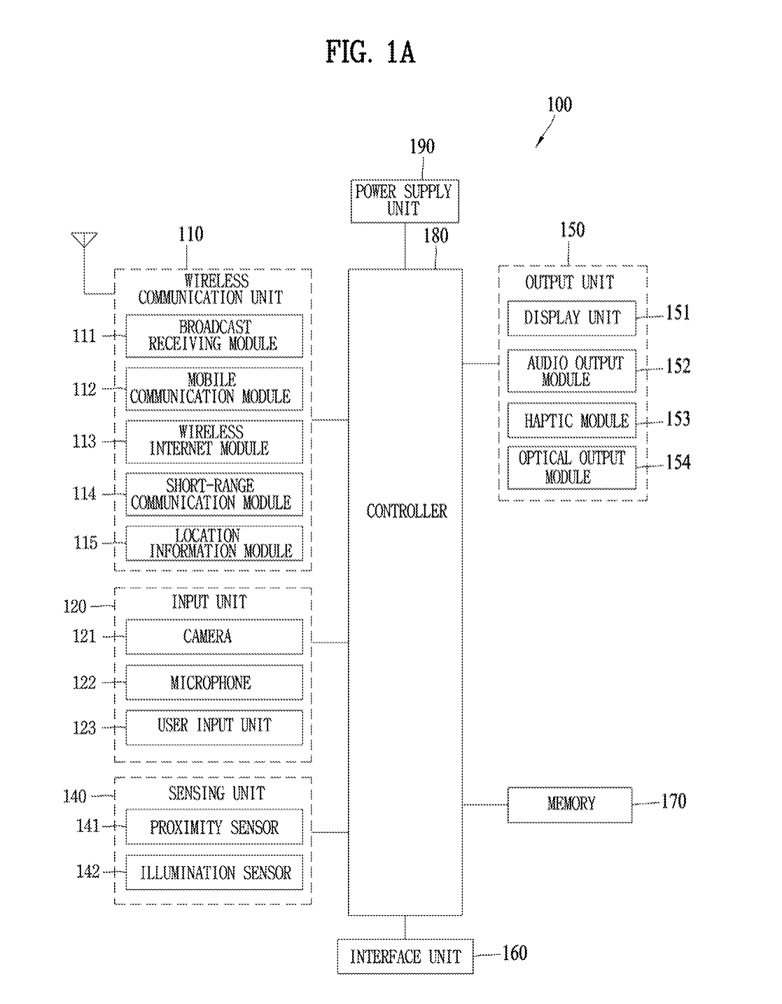

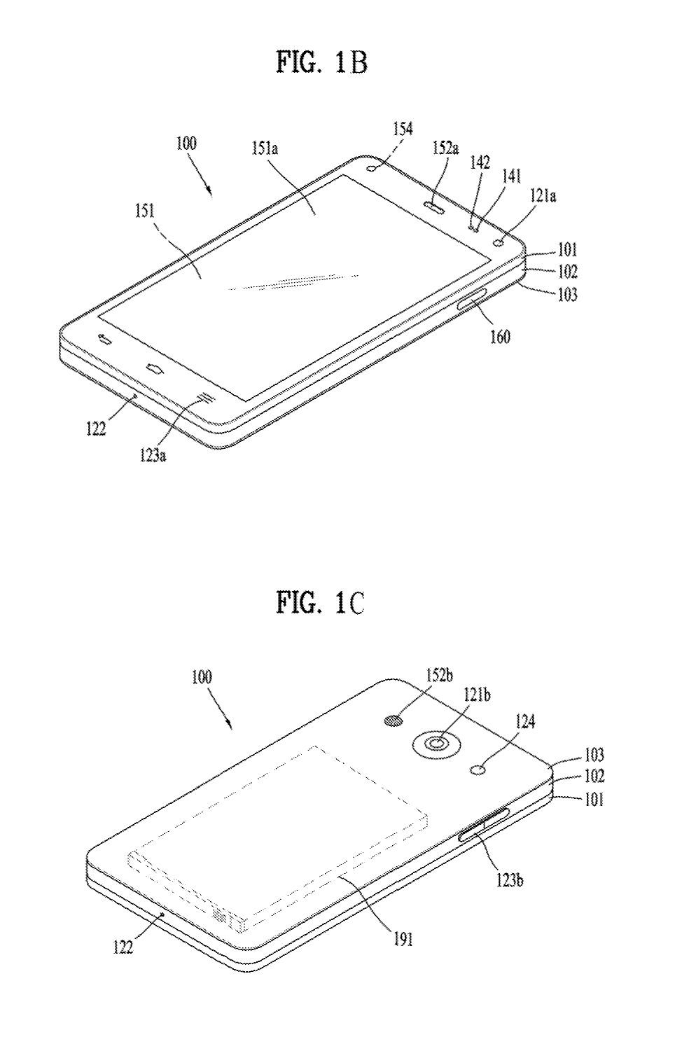

Reference is now made to FIGS. 1A-1C, where FIG. 1A is a block diagram of a mobile terminal in accordance with the present disclosure, and FIGS. 1B and 1C are conceptual views of one example of the mobile terminal, viewed from different directions.

The mobile terminal 100 is shown having components such as a wireless communication unit 110, an input unit 120, a sensing unit 140, an output unit 150, an interface unit 160, a memory 170, a controller 180, and a power supply unit 190. It is understood that implementing all of the illustrated components in The FIG. 1A is not a requirement, and that greater or fewer components may alternatively be implemented.

Referring now to FIG. 1A, the mobile terminal 100 is shown having wireless communication unit 110 configured with several commonly implemented components.

The wireless communication unit 110 typically includes one or more modules which permit communications such as wireless communications between the mobile terminal 100 and a wireless communication system, communications between the mobile terminal 100 and another mobile terminal, communications between the mobile terminal 100 and an external server. Further, the wireless communication unit 110 typically includes one or more modules which connect the mobile terminal 100 to one or more networks. To facilitate such communications, the wireless communication unit 110 includes one or more of a broadcast receiving module 111, a mobile communication module 112, a wireless Internet module 113, a short-range communication module 114, and a location information module 115.

The input unit 120 includes a camera 121 for obtaining images or video, a microphone 122, which is one type of audio input device for inputting an audio signal, and a user input unit 123 (for example, a touch key, a push key, a mechanical key, a soft key, and the like) for allowing a user to input information. Data (for example, audio, video, image, and the like) is obtained by the input unit 120 and may be analyzed and processed by controller 180 according to device parameters, user commands, and combinations thereof

The sensing unit 140 is typically implemented using one or more sensors configured to sense internal information of the mobile terminal, the surrounding environment of the mobile terminal, user information, and the like. For example, in FIG. 1A, the sensing unit 140 is shown having a proximity sensor 141 and an illumination sensor 142.

If desired, the sensing unit 140 may alternatively or additionally include other types of sensors or devices, such as a touch sensor, an acceleration sensor, a magnetic sensor, a G-sensor, a gyroscope sensor, a motion sensor, an RGB sensor, an infrared (IR) sensor, a finger scan sensor, a ultrasonic sensor, an optical sensor (for example, camera 121), a microphone 122, a battery gauge, an environment sensor (for example, a barometer, a hygrometer, a thermometer, a radiation detection sensor, a thermal sensor, and a gas sensor, among others), and a chemical sensor (for example, an electronic nose, a health care sensor, a biometric sensor, and the like), to name a few. The mobile terminal 100 may be configured to utilize information obtained from sensing unit 140, and in particular, information obtained from one or more sensors of the sensing unit 140, and combinations thereof

The output unit 150 is typically configured to output various types of information, such as audio, video, tactile output, and the like. The output unit 150 is shown having a display unit 151, an audio output module 152, a haptic module 153, and an optical output module 154.

The display unit 151 may have an inter-layered structure or an integrated structure with a touch sensor in order to facilitate a touch screen. The touch screen may provide an output interface between the mobile terminal 100 and a user, as well as function as the user input unit 123 which provides an input interface between the mobile terminal 100 and the user.

The interface unit 160 serves as an interface with various types of external devices that can be coupled to the mobile terminal 100. The interface unit 160, for example, may include any of wired or wireless ports, external power supply ports, wired or wireless data ports, memory card ports, ports for connecting a device having an identification module, audio input/output (I/O) ports, video I/O ports, earphone ports, and the like. In some cases, the mobile terminal 100 may perform assorted control functions associated with a connected external device, in response to the external device being connected to the interface unit 160.

The memory 170 is typically implemented to store data to support various functions or features of the mobile terminal 100. For instance, the memory 170 may be configured to store application programs executed in the mobile terminal 100, data or instructions for operations of the mobile terminal 100, and the like. Some of these application programs may be downloaded from an external server via wireless communication. Other application programs may be installed within the mobile terminal 100 at time of manufacturing or shipping, which is typically the case for basic functions of the mobile terminal 100 (for example, receiving a call, placing a call, receiving a message, sending a message, and the like). It is common for application programs to be stored in the memory 170, installed in the mobile terminal 100, and executed by the controller 180 to perform an operation (or function) for the mobile terminal 100.

The controller 180 typically functions to control overall operation of the mobile terminal 100, in addition to the operations associated with the application programs. The controller 180 processes signals, data, information and the like inputted or outputted through the above-mentioned components and/or runs application programs saved in the memory 170, thereby processing or providing a user with appropriate information and/or functions.

The controller 180 may provide or process information or functions appropriate for a user by processing signals, data, information and the like, which are input or output by the various components depicted in FIG. 1A, or activating application programs stored in the memory 170. As one example, the controller 180 controls some or all of the components illustrated in FIGS. 1A-1C according to the execution of an application program that have been stored in the memory 170.

The power supply unit 190 can be configured to receive external power or provide internal power in order to supply appropriate power required for operating elements and components included in the mobile terminal 100. The power supply unit 190 may include a battery, and the battery may be configured to be embedded in the terminal body, or configured to be detachable from the terminal body.

At least one portion of the respective components mentioned in the foregoing description can cooperatively operate to embody operations, controls or controlling methods of the mobile terminal according to various embodiments of the present invention mentioned in the following description. Moreover, the operations, controls or controlling methods of the mobile terminal can be embodied in the mobile terminal by running at least one or more application programs saved in the memory 170.

In the following detailed description, reference is made to the accompanying drawing figures which form a part hereof, and which show by way of illustration specific embodiments of the invention. It is to be understood by those of ordinary skill in this technological field that other embodiments may be utilized, and structural, electrical, as well as procedural changes may be made without departing from the scope of the present invention. Wherever possible, the same reference numbers will be used throughout the drawings to refer to the same or similar parts.

As used herein, the suffixes ‘module’, ‘unit’ and ‘part’ are used for elements in order to facilitate the disclosure only. Therefore, significant meanings or roles are not given to the suffixes themselves and it is understood that the ‘module’, ‘unit’ and ‘part’ can be used together or interchangeably.

Referring now to FIGS. 1B and 1C, the mobile terminal 100 is described with reference to a bar-type terminal body. However, the mobile terminal 100 may alternatively be implemented in any of a variety of different configurations.

Examples of such configurations include watch-type, clip-type, glasses-type, or as a folder-type, flip-type, slide-type, swing-type, and swivel-type in which two and more bodies are combined with each other in a relatively movable manner, and combinations thereof. Discussion herein will often relate to a particular type of mobile terminal (for example, bar-type, watch-type, glasses-type, and the like). However, such teachings with regard to a particular type of mobile terminal will generally apply to other types of mobile terminals as well.

The mobile terminal 100 will generally include a case (for example, frame, housing, cover, and the like) forming the appearance of the terminal. In this embodiment, the case is formed using a front case 101 and a rear case 102. Various electronic components are incorporated into a space formed between the front case 101 and the rear case 102. At least one middle case may be additionally positioned between the front case 101 and the rear case 102.

The display unit 151 is shown located on the front side of the terminal body to output information. As illustrated, a window 151a of the display unit 151 may be mounted to the front case 101 to form the front surface of the terminal body together with the front case 101.

In some embodiments, electronic components may also be mounted to the rear case 102. Examples of such electronic components include a detachable battery 191, an identification module, a memory card, and the like. Rear cover 103 is shown covering the electronic components, and this cover may be detachably coupled to the rear case 102. Therefore, when the rear cover 103 is detached from the rear case 102, the electronic components mounted to the rear case 102 are externally exposed.

As illustrated, when the rear cover 103 is coupled to the rear case 102, a side surface of the rear case 102 is partially exposed. In some cases, upon the coupling, the rear case 102 may also be completely shielded by the rear cover 103. In some embodiments, the rear cover 103 may include an opening for externally exposing a camera 121b or an audio output module 152b.

The cases 101, 102, 103 may be formed by injection-molding synthetic resin or may be formed of a metal, for example, stainless steel (STS), aluminum (Al), titanium (Ti), or the like.

As an alternative to the example in which the plurality of cases form an inner space for accommodating components, the mobile terminal 100 may be configured such that one case forms the inner space. In this example, a mobile terminal 100 having a uni-body is formed in such a manner that synthetic resin or metal extends from a side surface to a rear surface.

If desired, the mobile terminal 100 may include a waterproofing unit (not shown) for preventing introduction of water into the terminal body. For example, the waterproofing unit may include a waterproofing member which is located between the window 151a and the front case 101, between the front case 101 and the rear case 102, or between the rear case 102 and the rear cover 103, to hermetically seal an inner space when those cases are coupled.

The mobile terminal 100 may be provided with the display unit 151, the first audio output unit 152a, the second audio output unit 152b, the proximity sensor 141, the illumination sensor 142, the optical output unit 154, the first camera 121a, the second camera 121b, the first manipulating unit 123a, the second manipulating unit 123b, the microphone 122, the interface unit 160, and the like.

FIGS. 1B and 1C depict certain components as arranged on the mobile terminal. However, it is to be understood that alternative arrangements are possible and within the teachings of the instant disclosure. Some components may be omitted or rearranged. For example, the first manipulation unit 123a may be located on another surface of the terminal body, and the second audio output module 152b may be located on the side surface of the terminal body.

The display unit 151 outputs information processed in the mobile terminal 100. The display unit 151 may be implemented using one or more suitable display devices. Examples of such suitable display devices include a liquid crystal display (LCD), a thin film transistor-liquid crystal display (TFT-LCD), an organic light emitting diode (OLED), a flexible display, a 3-dimensional (3D) display, an e-ink display, and combinations thereof

The display unit 151 may be implemented using two display devices, which can implement the same or different display technology. For instance, a plurality of the display units 151 may be arranged on one side, either spaced apart from each other, or these devices may be integrated, or these devices may be arranged on different surfaces.

The display unit 151 may also include a touch sensor which senses a touch input received at the display unit. When a touch is input to the display unit 151, the touch sensor may be configured to sense this touch and the controller 180, for example, may generate a control command or other signal corresponding to the touch. The content which is input in the touching manner may be a text or numerical value, or a menu item which can be indicated or designated in various modes.

The touch sensor may be configured in a form of a film having a touch pattern, disposed between the window 151a and a display on a rear surface of the window 151a, or a metal wire which is patterned directly on the rear surface of the window 151a. Alternatively, the touch sensor may be integrally formed with the display. For example, the touch sensor may be disposed on a substrate of the display or within the display.

The display unit 151 may also form a touch screen together with the touch sensor. Here, the touch screen may serve as the user input unit 123 (see FIG. 1A). Therefore, the touch screen may replace at least some of the functions of the first manipulation unit 123a.

The first audio output module 152a may be implemented in the form of a speaker to output voice audio, alarm sounds, multimedia audio reproduction, and the like.

The window 151a of the display unit 151 will typically include an aperture to permit audio generated by the first audio output module 152a to pass. One alternative is to allow audio to be released along an assembly gap between the structural bodies (for example, a gap between the window 151a and the front case 101). In this case, a hole independently formed to output audio sounds may not be seen or is otherwise hidden in terms of appearance, thereby further simplifying the appearance and manufacturing of the mobile terminal 100.

The optical output module 154 can be configured to output light for indicating an event generation. Examples of such events include a message reception, a call signal reception, a missed call, an alarm, a schedule notice, an email reception, information reception through an application, and the like. When a user has checked a generated event, the controller can control the optical output unit 154 to stop the light output.

The first camera 121a can process image frames such as still or moving images obtained by the image sensor in a capture mode or a video call mode. The processed image frames can then be displayed on the display unit 151 or stored in the memory 170.

The first and second manipulation units 123a and 123b are examples of the user input unit 123, which may be manipulated by a user to provide input to the mobile terminal 100. The first and second manipulation units 123a and 123b may also be commonly referred to as a manipulating portion, and may employ any tactile method that allows the user to perform manipulation such as touch, push, scroll, or the like. The first and second manipulation units 123a and 123b may also employ any non-tactile method that allows the user to perform manipulation such as proximity touch, hovering, or the like.

FIG. 1B illustrates the first manipulation unit 123a as a touch key, but possible alternatives include a mechanical key, a push key, a touch key, and combinations thereof.

Input received at the first and second manipulation units 123a and 123b may be used in various ways. For example, the first manipulation unit 123a may be used by the user to provide an input to a menu, home key, cancel, search, or the like, and the second manipulation unit 123b may be used by the user to provide an input to control a volume level being output from the first or second audio output modules 152a or 152b, to switch to a touch recognition mode of the display unit 151, or the like.

As another example of the user input unit 123, a rear input unit (not shown) may be located on the rear surface of the terminal body. The rear input unit can be manipulated by a user to provide input to the mobile terminal 100. The input may be used in a variety of different ways. For example, the rear input unit may be used by the user to provide an input for power on/off, start, end, scroll, control volume level being output from the first or second audio output modules 152a or 152b, switch to a touch recognition mode of the display unit 151, and the like. The rear input unit may be configured to permit touch input, a push input, or combinations thereof

The rear input unit may be located to overlap the display unit 151 of the front side in a thickness direction of the terminal body. As one example, the rear input unit may be located on an upper end portion of the rear side of the terminal body such that a user can easily manipulate it using a forefinger when the user grabs the terminal body with one hand. Alternatively, the rear input unit can be positioned at most any location of the rear side of the terminal body.

Embodiments that include the rear input unit may implement some or all of the functionality of the first manipulation unit 123a in the rear input unit. As such, in situations where the first manipulation unit 123a is omitted from the front side, the display unit 151 can have a larger screen.

As a further alternative, the mobile terminal 100 may include a finger scan sensor which scans a user's fingerprint. The controller 180 can then use fingerprint information sensed by the finger scan sensor as part of an authentication procedure. The finger scan sensor may also be installed in the display unit 151 or implemented in the user input unit 123.

The microphone 122 is shown located at an end of the mobile terminal 100, but other locations are possible. If desired, multiple microphones may be implemented, with such an arrangement permitting the receiving of stereo sounds.

The interface unit 160 may serve as a path allowing the mobile terminal 100 to interface with external devices. For example, the interface unit 160 may include one or more of a connection terminal for connecting to another device (for example, an earphone, an external speaker, or the like), a port for near field communication (for example, an Infrared Data Association (IrDA) port, a Bluetooth port, a wireless LAN port, and the like), or a power supply terminal for supplying power to the mobile terminal 100. The interface unit 160 may be implemented in the form of a socket for accommodating an external card, such as Subscriber Identification Module (SIM), User Identity Module (UIM), or a memory card for information storage.

The second camera 121b is shown located at the rear side of the terminal body and includes an image capturing direction that is substantially opposite to the image capturing direction of the first camera unit 121a. If desired, second camera 121a may alternatively be located at other locations, or made to be moveable, in order to have a different image capturing direction from that which is shown.

The second camera 121b can include a plurality of lenses arranged along at least one line. The plurality of lenses may also be arranged in a matrix configuration. The cameras may be referred to as an “array camera.” When the second camera 121b is implemented as an array camera, images may be captured in various manners using the plurality of lenses and images with better qualities.

As shown in FIG. 1C, a flash 124 is shown adjacent to the second camera 121b. When an image of a subject is captured with the camera 121b, the flash 124 may illuminate the subject.

As shown in FIG. 1B, the second audio output module 152b can be located on the terminal body. The second audio output module 152b may implement stereophonic sound functions in conjunction with the first audio output module 152a, and may be also used for implementing a speaker phone mode for call communication.

At least one antenna for wireless communication may be located on the terminal body. The antenna may be installed in the terminal body or formed by the case. For example, an antenna which configures a part of the broadcast receiving module 111 may be retractable into the terminal body. Alternatively, an antenna may be formed using a film attached to an inner surface of the rear cover 103, or a case that includes a conductive material.

A power supply unit 190 for supplying power to the mobile terminal 100 may include a battery 191, which is mounted in the terminal body or detachably coupled to an outside of the terminal body. The battery 191 may receive power via a power source cable connected to the interface unit 160. Also, the battery 191 can be recharged in a wireless manner using a wireless charger. Wireless charging may be implemented by magnetic induction or electromagnetic resonance.

The rear cover 103 is shown coupled to the rear case 102 for shielding the battery 191, to prevent separation of the battery 191, and to protect the battery 191 from an external impact or from foreign material. When the battery 191 is detachable from the terminal body, the rear case 103 may be detachably coupled to the rear case 102.

An accessory for protecting an appearance or assisting or extending the functions of the mobile terminal 100 can be provided on the mobile terminal 100. As one example of an accessory, a cover or pouch for covering or accommodating at least one surface of the mobile terminal 100 may be provided. The cover or pouch may cooperate with the display unit 151 to extend the function of the mobile terminal 100. Another example of the accessory is a touch pen for assisting or extending a touch input to a touch screen.

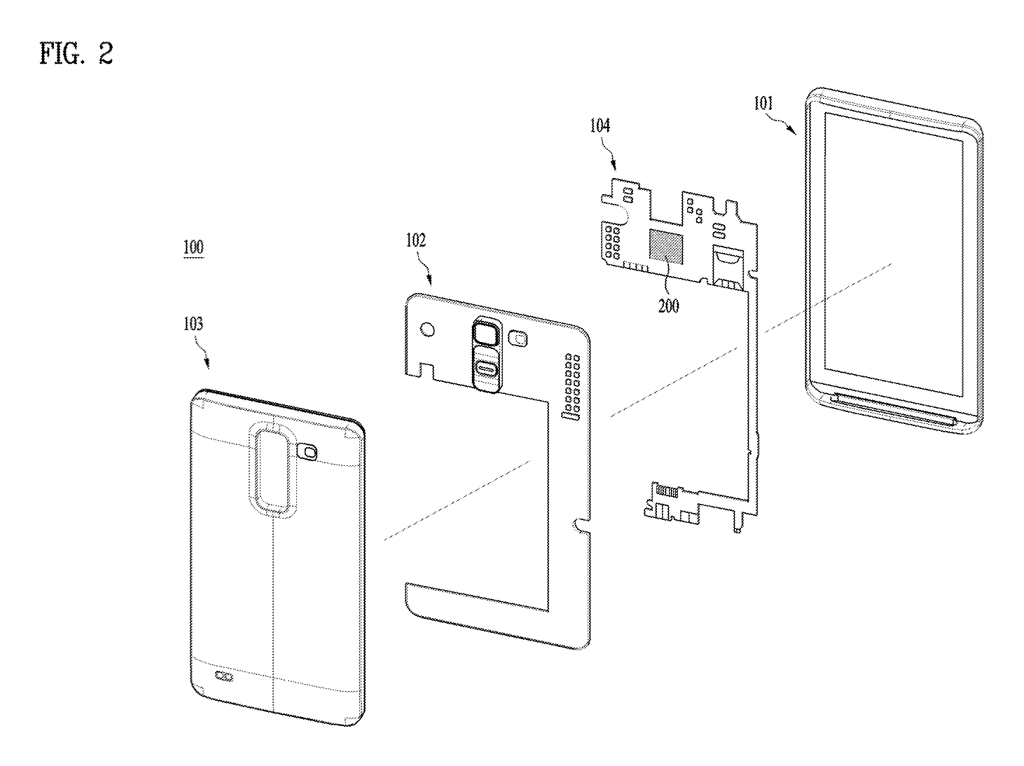

FIG. 2 is an exploded perspective diagram of the mobile terminal.

The printed circuit board 104 is fixedly mounted in the internal space defined by the front and rear cases. Especially, the main printed circuit board 104 in which most of electronic components are mounted only to provide a hub of electronic control for a mobile terminal. The main printed circuit board may be structured to be fixedly mounted in one of the front, rear case and middle cases.

The main printed circuit board 104 may be disposed in parallel to the front or rear surface and have electronic components loaded mounted in a front or rear surface thereof, only to minimize the overall thickness of the mobile terminal.

The main printed circuit board 104 may be arranged in a predetermined portion avoiding the portions where main components including a battery are disposed, according to the demand for miniaturization of the mobile terminal. For example, the main printed circuit board 104 may be provided in ‘I’-shape or a ‘⊏’ shape.

At least one of the embodiments which will be described later adapts the main printed circuit board 104 in which key components are mounted and any types of printed circuit boards may be applied to the embodiments, only unless related to the purpose of the present disclosure.

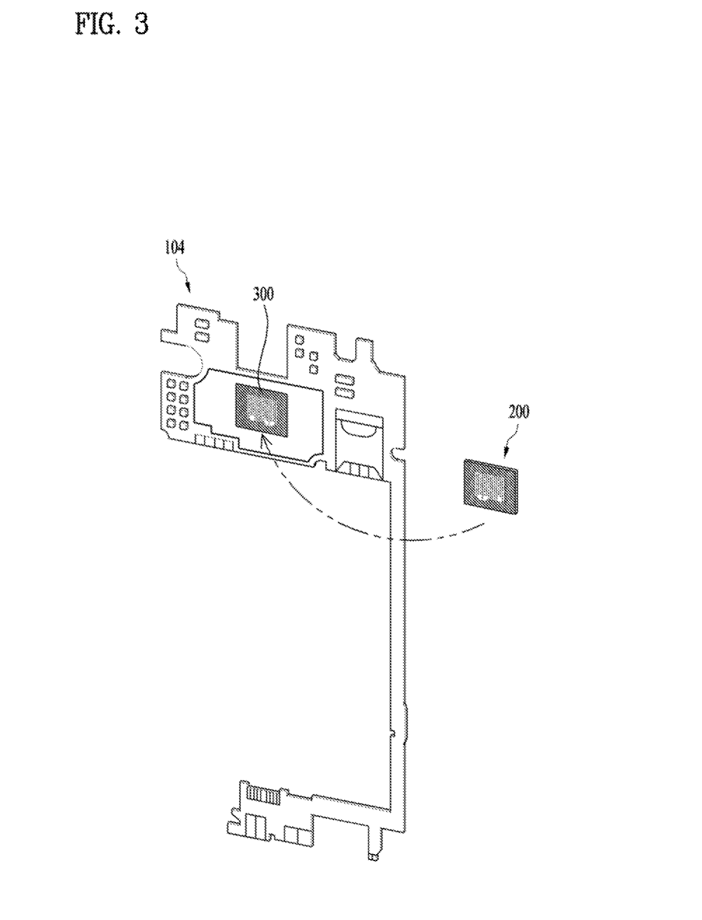

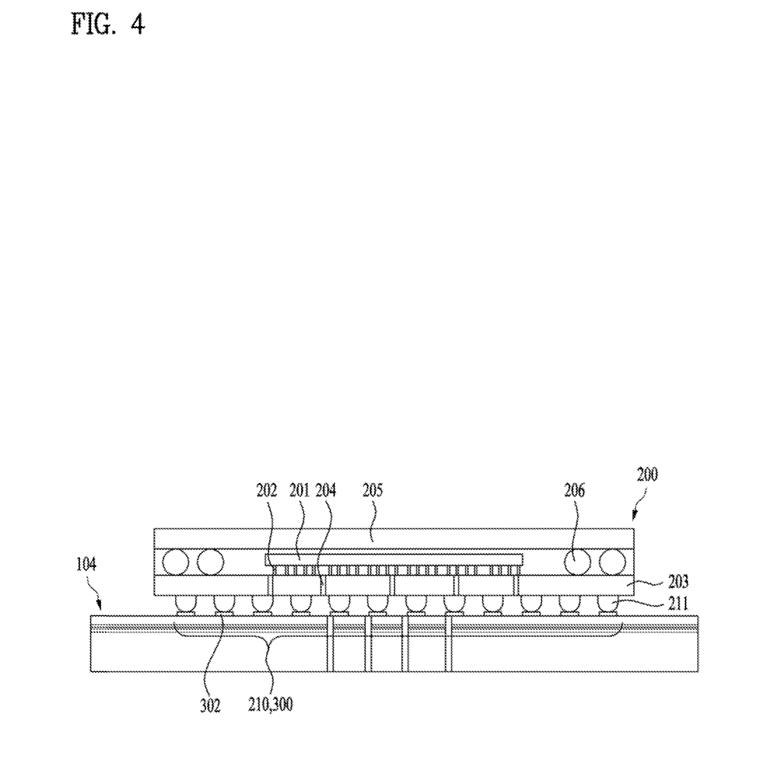

FIG. 3 is a conceptual diagram of the chipset 200 and the printed circuit board 104 before they are soldered to each other and FIG. 4 is a conceptual diagram of the chipset 200 and the printed circuit board 104 after they are soldered to each other.

The chipset 200 is loaded in the printed circuit board 104 as one of the electronic components mentioned above and performs an electronic function.

Especially, the chipset 200 may mean an application processor for functioning as a brain of the mobile terminal, in other words, System-On-Chip.

The system-on-chip is configured to perform as one or more of CPU, memory, codec, camera and audio and then diverse functions. Accordingly, the system-on-chip is not free from heat generation and could require a higher connecting reliability.

The chipset 200 shown in the drawing may include a chip for performing a memory function and double boards, specifically, an upper substrate 205 and a lower substrate 203. As occasion demands, a single board type chipset may be provided as the chipset 200. In case of the double board type, the upper substrate 205 and the lower substrate 203 are electrically connected by a filler 206.

The chipset 200 may be soldered to the printed circuit board 104. The soldering connection means that the conductive terminals loaded in the chipset 200 and the conductive terminals loaded in the printed circuit board 104 are aligned and soldered to be electrically connected with each other.

The conductive terminal of the chipset 200 may be a solder ball 211 which will be described later and the conductive terminal of the printed circuit board 104 may be a pad 302. Both are operatively coupled to each other by a soldering material such as a solder paste.

A single chipset 200 may have a plurality of terminals to transmit and receive diverse signals. The terminals may be typically aligned in an array type.

The connection between the array type solder balls 211 and the pads 302 may be BGA (Ball Grid Array) Soldering. The array type of the solder balls 211 provided in the chipset 200 may be defined as the BGA 210. The array type of the pads provided in the printed circuit board 104 may be defined as the solder pad array 300.

As mentioned above, the reliability of the connection between the coupled chipset 200 and the printed circuit board 104 becomes an issue in heat resistance and impact resistance.

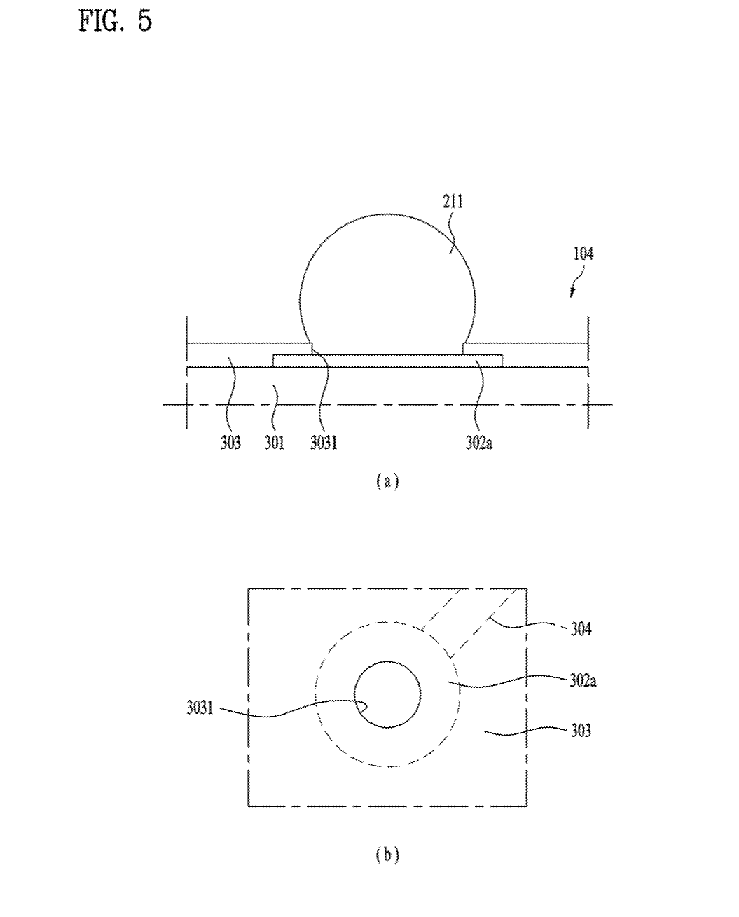

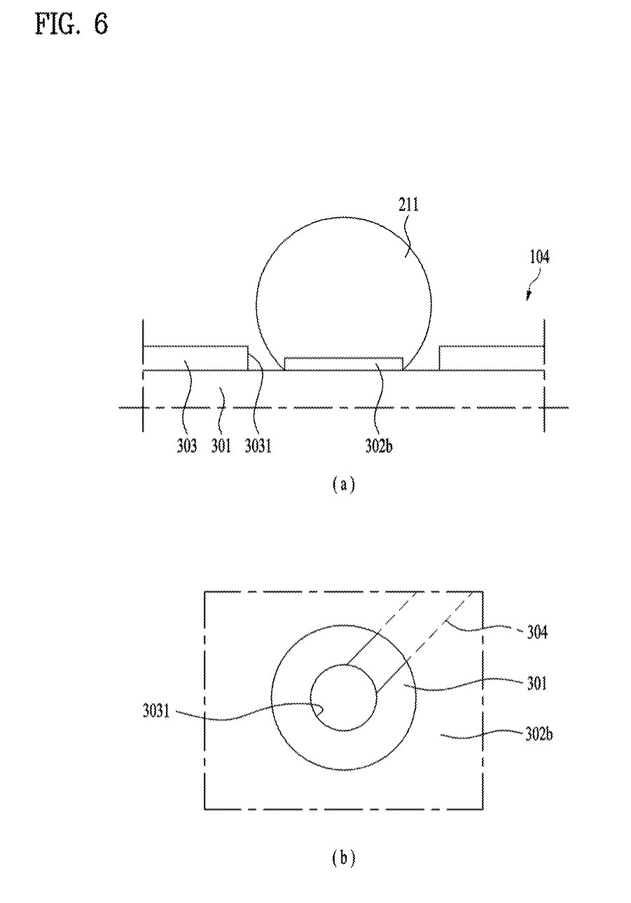

FIGS. 5 and 6 are diagrams illustrating the connection between the printed circuit board 104 and the solder balls 211.

The connection between the solder balls 211 and the printed circuit board 104 may be realized into SMD (Solder Mask Defined) and NSMD (Non-Solder mask Defined) according to the type of the pad 302.

FIG. 5 (a) is a sectional diagram illustrating the SMD connection between the printed circuit board 104 and the solder ball 211 and FIG. 5 (b) is a diagram illustrating the SMD solder surface of the printed circuit board 104.

FIG. 6 (a) is a sectional diagram illustrating the NSMD connection between the printed circuit board 104 and the solder ball 211. FIG. 6 (b) is a diagram illustrating the NSMD surface of the printed circuit board 104.

The printed circuit board 104 is made of some materials, for example, BT (Bismaleimide Triazine) resin.

The pad 302 is provided on a surface of the printed circuit board 302 as conductive material. The pad 302 provides a place to which the solder ball 211 of the BGA package 210 is coupled.

The pad 302 may include copper which is capable of performing a conduction function with a less expensive price.

The solder mask 303 covers the printed circuit board 104 to minimize a risk that neighboring pads 302 are electrically connected with each other.

A metal wire 304 electrically connected with the pad 302 may be provided in the printed circuit board 104. The pattern of the metal wire 304 forms diverse passages according to functions to be connected to different electronic components, respectively.

The solder ball 211 is electrically connected with the metal wire 304 via the pad 302.

As mentioned above, the reliability of the connection between the solder ball 211 and the pad 302 becomes an issue.

The SMD printed circuit board 104 shown in FIG. 5 covers a predetermined region of the pad 302a. In other words, an edge region of the pad 302a is covered is the solder mask 303 not to expose the non-conductive board 301 outside.

As the pad 302a is supported by the solder mask 303, the pad 302a or the metal wire 304 may not be separated from the printed circuit board 104 by an external shock.

As the solder ball 211 is connected only on the pad 302a, the solder ball 211 is able to be connected without being deformed during the soldering process advantageously.

Neighboring solder mask 303 and the solder ball are made of different materials. In case heat is generated, different coefficients of linear expansion might cause some fatigue. Because of that, the solder ball 211 might be separated or there might be a crack near a border region 3031 of the solder mask 303 disadvantageously.

In the NSMD shown in FIG. 6 compared with the SMD, the pad 302b with a relatively narrow region is formed and the solder mask 303 is provided not to cover the pad 302b to expose some region of the non-conductive board 301.

The solder ball 211 is connected while surrounding upper and lateral surfaces of the pad 302 and capable of enhancing the soldering connection performance. Accordingly, the phenomena occur less such as the separation of the solder ball 211 and the crack generated near the border region 3031 of the solder mask 303 which might be caused by the rise of the temperature, compared with the SMD. However, the pad 302b is not supported by the solder mask 303 and it is highly possible for the pad 302b or the metal wire 304 to be separated from the printed circuit board 104.

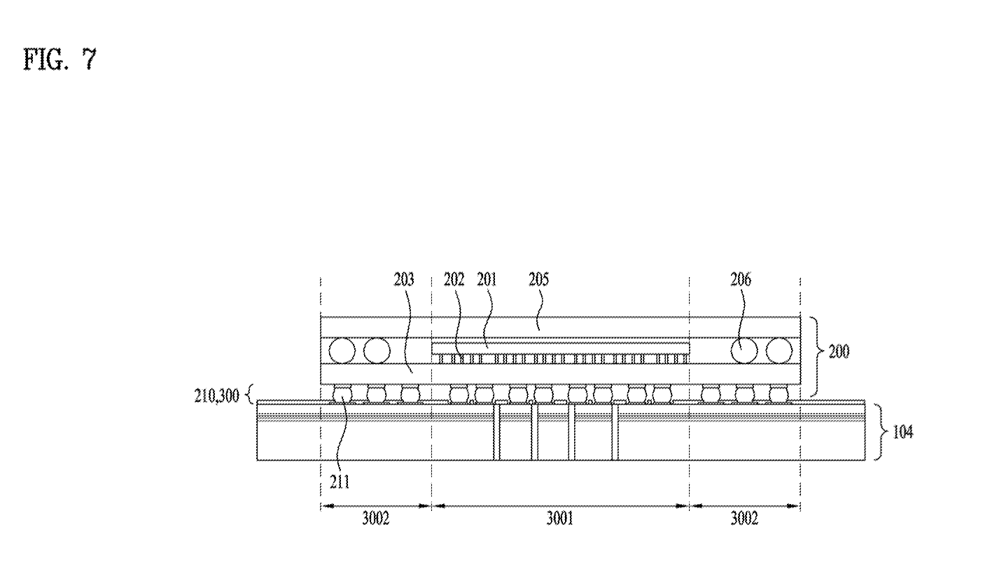

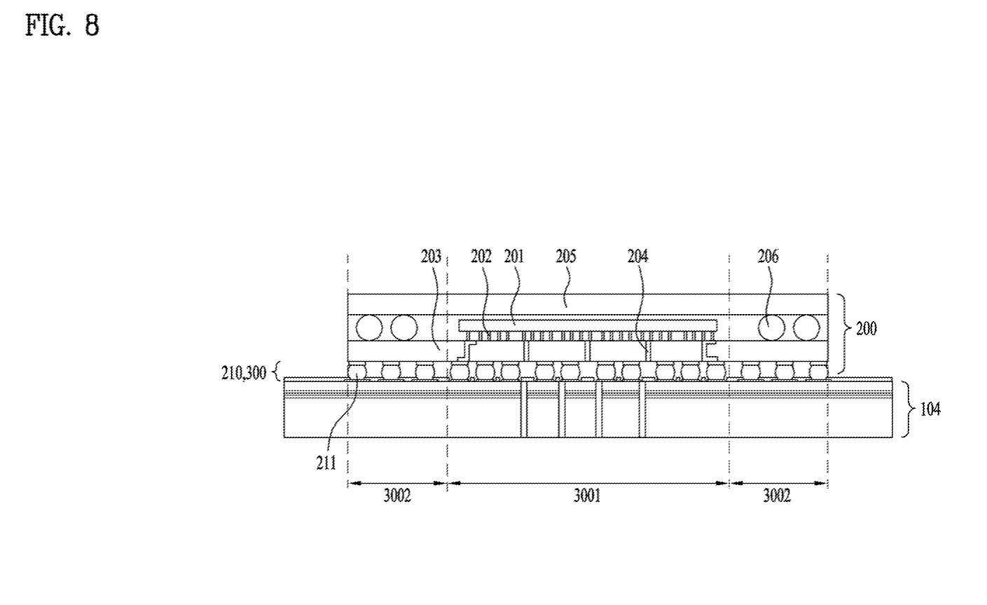

FIGS. 7 and 8 are conceptual diagrams illustrating the connection between the printed circuit board 104 and the chipset 200 according to different embodiments.

The chipset 200 includes a die 201 having a plurality of direct circuits and configured to perform a function of a semiconductor.

The die 201 becomes a region where heat is generated in the chipset 200. Accordingly, a region of the solder pad array 300 corresponding to the die 201 may be a NSMD array region 3001 configured of NSMD pad 302 arrays and the other region of the solder pad array 300 is a SMD array region 3002 configured of SMD pad arrays.

In case the die 201 is formed in a central region of the chipset 200, the NSMD array region 3001 is arranged in a central region of the solder pad array and the SMD array region 3002 is arranged in an outer region of the solder pad array 300.

An outer region is more sensitive to an external shock than an inner region of the printed circuit board 104. When the SMD array region is provided in the other region and the NSMD array region 3001 in the inner region, the outer SMD array region 3002 becomes resistant with respect to such an external shock and the NSMD array region 3001 becomes resistant with respect to the heat intensively generated in the printed circuit board 104.

More specifically, an edge of the NSMD array region 3001 may be corresponding to an edge of the die 201 shown in FIG. 7. Strictly speaking, the edge of the NSMD array region 3001 is corresponding to a perpendicular region of the edge of the die 201 with respect to the solder surface of the printed circuit board 104.

Alternatively, the edge of the NSMD array region 3001 may be corresponding to an edge of the BGA 210 directly connected to the die 201.

The die 201 may be electrically connected with the solder ball 211 through a bump 202 and a Via 204 of the low substrate 203.

A BGA 210 region of the solder balls 211 directly connected to the die 201 is defined as a first BGA 210 region and the other BGA region except the first BGA region is defined as a second BGA region.

The first BGA region is employed to supply electric power to the die 201 and the second BGA region to transmit and receive data.

Accordingly, heat is intensively generated in the first BGA region, compared with the second BGA region.

The solder pad array 300 region in which the solder balls 211 of the first BGA region are soldered may be arranged in NSMD array region 3001. The solder pad array 300 region in which the solder balls 211 of the second BGA region are soldered may be arranged in the SMD array region 3002.

More specifically, a border between the NSMD array region 3001 and the SMD array region 3002 may be set based on a physical edge of the die 201 as shown in FIG. 7 or an edge of the BGA region directly connected with the die 201 as shown in FIG. 8.

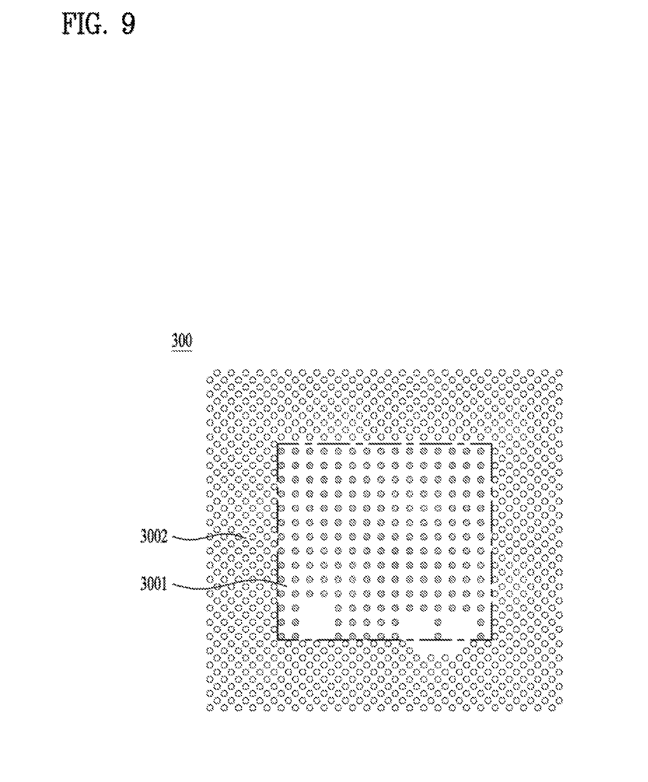

FIG. 9 illustrates one embodiment of the solder pad array 300 related to the present disclosure.

When the chipset 200 has a rectangular alignment of the BGA 210, the solder pad array 300 may also have a rectangular alignment.

In case the die 201 is arranged in the central portion of the chipset 200, the SMD array region 3002 may form ‘□’ shape according to the principle mentioned above and the NSMD array region 3001 is located in the SMD array region 3002 to form a rectangular shape filled with the SMD pads 302.

Outer ‘n’ lines are formed by the SMD array region 3002 and an inner portion of the SMD array region 3002 is filled with the NSMD array region 3001.

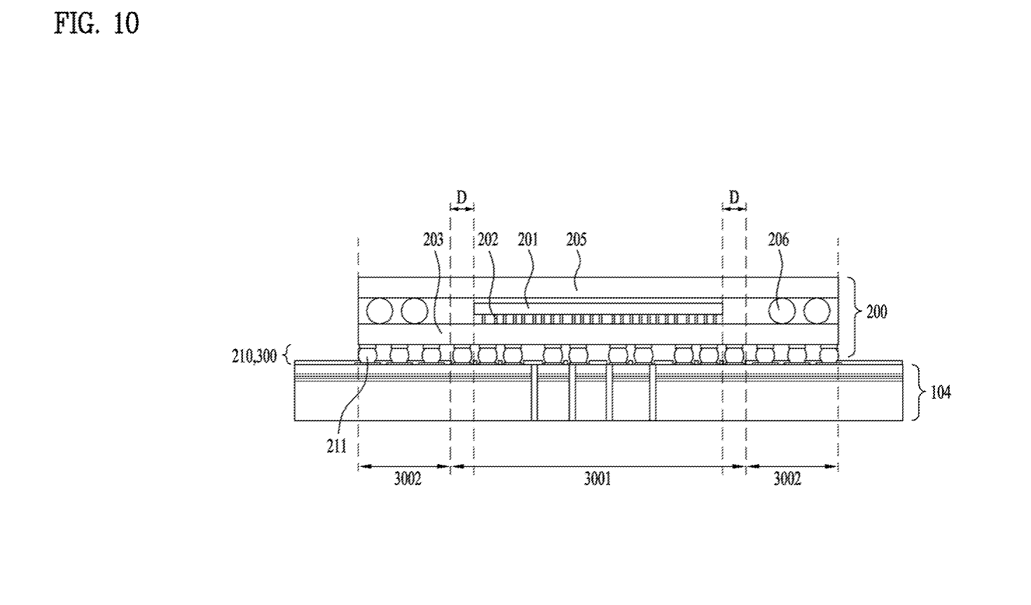

FIG. 10 illustrates another embodiment of a solder cross section between the printed circuit board 104 and the chipset 200.

Different from the embodiment shown in FIG. 7 or 8, the NSMD array region 3001 may be arranged to an expanded edge as far as a specific ‘D’ from the edge corresponding to the die 201.

Generally, heat generation affects reliability of the soldering connection than impacts. The region affected by the heat is reduced serially not reduced from a specific edge region non-serially. Considering the effect of the heat generation on the soldering connection more, the NSMD array region 3001 may be also expanded farther than the reference edge shown in FIG. 7 or 8.

The edge of the NSMD array region 3001 may be located in a portion as expanded more outward as specific ‘D’ than the edge of the die 201 or the edge of the first BA region.

The specific region ‘D’ may be a singular line pad region or plural lines pad region.

In contrast, when the effect of the physical impact on the soldering connection has to be considered more than the effect of the heat generation, the SMD array region 3002 may be expanded more than the reference edge of FIG. 7 or 8. Accordingly, the NSMD array region 3001 may be relatively reduced more than the reference edge of FIG. 7 or 8.

In other words, the edge of the NSMD array region 3001 may be located in an inner portion as far as specific ‘D’, compared with the edge of the die 201 or the first BGA region (not shown).

The expanded distance of the SMD array region 3002 may be the singular line pad region such as the specific ‘D’ of the embodiment or plural lines pad region.

The expansion of the SMD array region 3002 may be applied in case there is a portion specifically vulnerable to impacts in the printed circuit board 104 or little effect of the heat generation. For example, it may be applied when the chipset 200 is mounted in an outer portion or an opening near portion of the printed circuit board 104 or the chipset 200 such as a memory semiconductor having relatively less heat generation is mounted.

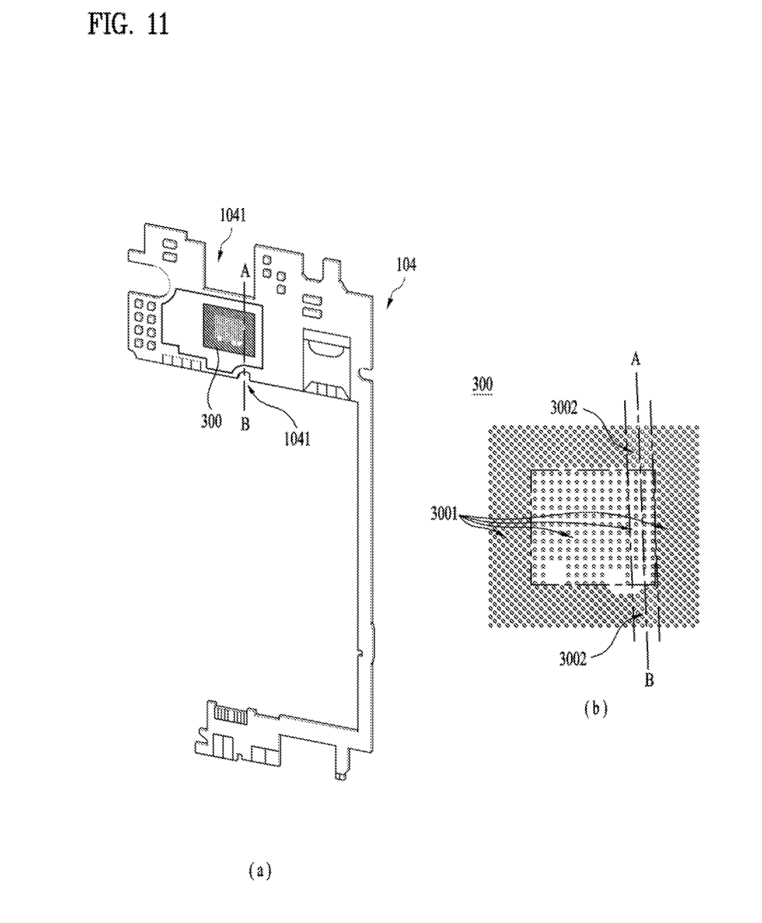

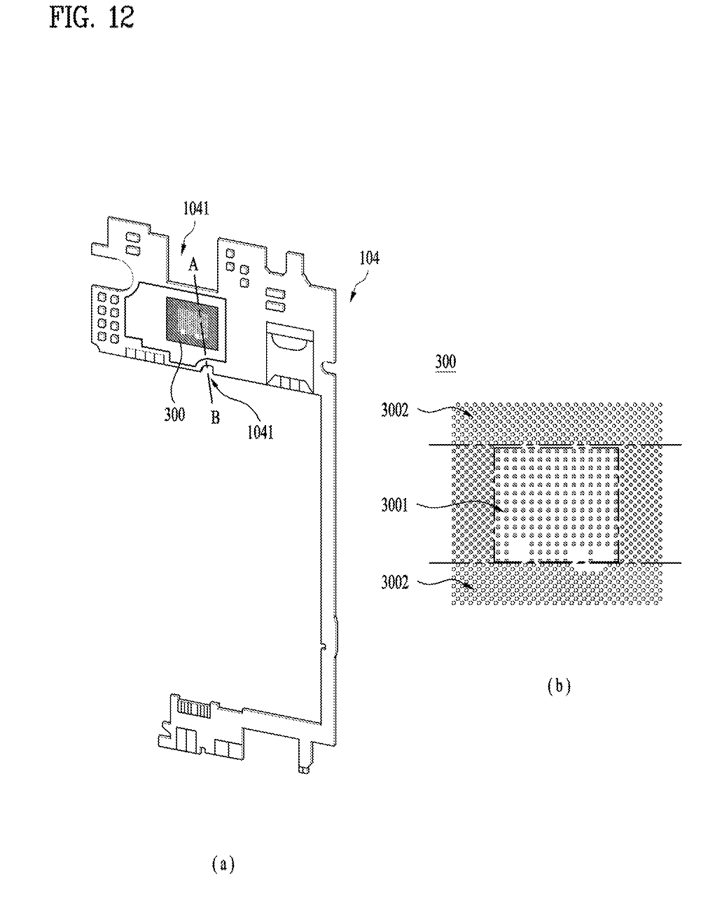

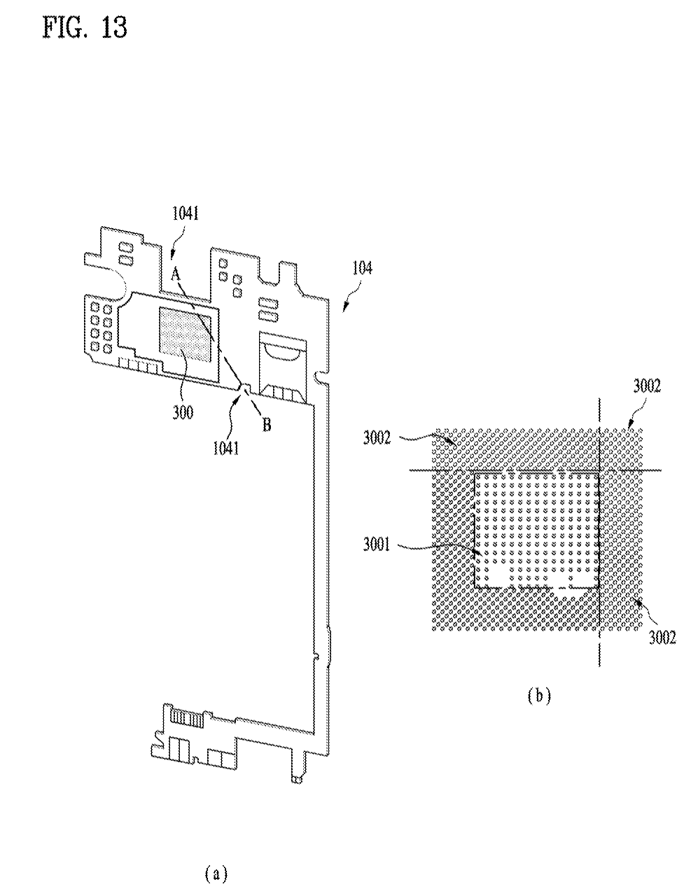

FIGS. 11, 12 and 13 illustrate further different embodiments of the printed circuit board 104 related to the present disclosure.

As mentioned above, the printed circuit board 104 may be provided in diverse shapes. The location where the chipset 200 is mounted may be variable diversely. The region having the external shock or impact may be differentiated by the geometric shape of the printed circuit board 104. Considering that, the NSMD array region 3001 and the SMD array region 3002 may be arranged.

For example, when the chipset 200 is mounted between two cut-off regions 1041 formed in the printed circuit board 104, the distance between the two cut-off regions 1041, in other words, a short-length portion has a relatively low strength and more fatigue might occur. The portion where the greatest fatigue is applied may be defined as A-B line.

In this instance, the SMD array region 3002 shown in FIG. 11 may form a predetermined width along the A-B line. It is required to secure the NSMD array region 3001 considering the least heat generation. In other words, the SMD array region 3002 is arranged in the predetermined width along the A-B line. Although the central portion having the heat generation of the die 201 is overlapped with the A-B line, the NSMD array region 3001 may be arranged in the central portion.

Alternatively, the principle may be expanded and may be applied only to the corners of the rectangular-shaped solder pad array 300 region where the relatively more fatigue is generated. Even in this instance, the SMD array region 3002 may be applied only to the portion corresponding to corners of the rectangular solder which meets the A-B line.

The corners may be two corners facing each other or arranged side by side according to the region of the A-B line and the chipset 200.

As the present features may be embodied in several forms without departing from the characteristics thereof, it should also be understood that the above-described embodiments are not limited by any of the details of the foregoing description, unless otherwise specified, but rather should be considered broadly within its scope as defined in the appended claims, and therefore all changes and modifications that fall within the metes and bounds of the claims, or equivalents of such metes and bounds, are therefore intended to be embraced by the appended claims.

What is claimed is:

1. A mobile terminal comprising:
a printed circuit board;
a chipset having a die;
a Ball Grid Array (BGA) connecting the chipset to the printed circuit board; and
a solder pad array provided in a predetermined region of the printed circuit board, the solder pad array corresponding to the BGA, the solder pad array including:
a Non-Solder Mask Defined (NSMD) array region provided at a region of the printed circuit board corresponding to the die and having NSMD pads; and
a Solder Mask Defined (SMD) array region provided at a region of the printed circuit board located at an outer portion of the NSMD array region and having SMD pads.

2. The mobile terminal of claim 1, wherein the SMD array region is provided outside of an edge of the die when viewed in a direction normal to a surface of the die, and
wherein the NSMD array region is provided inside of the edge of the die when viewed in the direction normal to the surface of the die.

3. The mobile terminal of claim 1, wherein the BGA comprises:
a first BGA region connected to the die through a bump; and
a second BGA region connected to the chipset except where the first BGA region is connected to the die, and
wherein the NSMD array region corresponds to the first BGA region and the SMD array region corresponds to the second BGA region.

4. The mobile terminal of claim 3, further comprising a battery,
wherein the first BGA region is configured to supply electric power from the battery to the die.

5. The mobile terminal of claim 4, wherein the chipset includes a plurality of terminals to transmit and receive signals, and
wherein the second BGA region is connected to the plurality of terminals.

6. The mobile terminal of claim 1, wherein a border between the NSMD array region and the SMD array region corresponds to a perimeter of the die.

7. The mobile terminal of claim 1, wherein a border between the NSMD array region and the SMD array region is spaced a predetermined distance from a perimeter of the die when viewed normal to an upper surface of the die.

8. The mobile terminal of claim 1, wherein an outermost line of the solder pad array forms a rectangular shape.

9. The mobile terminal of claim 6, wherein the SMD array region forms a ‘□’ shape, and
wherein the NSMD array region is provided in an interior of the ‘□’ shaped SMD array region.

10. The mobile terminal of claim 1, wherein the chipset is a system-on-chip.

11. A printed circuit board assembly comprising:
a printed circuit board;
a chipset having a die;
a Ball Grid Array (BGA) connecting the chipset to the printed circuit board; and
a solder pad array provided in a predetermined region of the printed circuit board, the solder pad array corresponding to the BGA, the solder pad array including:
a Non-Solder Mask Defined (NSMD) array region provided at a region of the printed circuit board corresponding to the die and having NSMD pads; and
a Solder Mask Defined (SMD) array region provided at a region of the printed circuit board located at an outer portion of the NSMD array region and having SMD pads.

12. The printed circuit board assembly of claim 11, wherein the SMD array region is provided outside of an edge of the die when viewed in a direction normal to a surface of the die, and
wherein the NSMD array region is provided inside of the edge of the die when viewed in the direction normal to the surface of the die.

13. The printed circuit board assembly of claim 11, wherein the BGA comprises:
a first BGA region connected to the die through a bump; and
a second BGA region connected to the chipset except where the first BGA region is connected to the die, and
wherein the NSMD array region corresponds to the first BGA region and the SMD array region corresponds to the second BGA region.

14. The printed circuit board assembly of claim 13, wherein the chipset includes a plurality of terminals to transmit and receive signals, and
wherein the second BGA region is connected to the plurality of terminals.

15. The printed circuit board assembly of claim 13, wherein a border between the NSMD array region and the SMD array region is spaced a predetermined distance from a perimeter of the die when viewed normal to an upper surface of the die.

16. The printed circuit board assembly of claim 11, wherein an outermost line of the solder pad array forms a rectangular shape.

17. The printed circuit board assembly of claim 11, wherein the chipset is a system-on-chip.

18. A mobile terminal comprising:
a non-conductive substrate; and
a solder pad array provided at a predetermined region of the non-conductive substrate, the solder pad array including:
a SMD (Solder Mask Defined) array region having a plurality of outer lines of SMD pads; and
a NSMD (Non-Solder Mask Defined) array region provided in the SMD array region and having NSMD pads.

19. The mobile terminal of claim 18, wherein an outermost line of the plurality of outer lines of SMD pads forms a rectangular shape.

20. The mobile terminal of claim 19, wherein the SMD array region forms a ‘□’ shape, and
wherein the NSMD array region is provided in an interior of the ‘□’ shaped SMD array region.
